(19) United States
(12) Patent Application Publication
(10) Pub. No.: US 2012/0061542 A1
(43) Pub. Date: Mar. 15, 2012

(54) SECURE COMPUTER TABLET ENCLOSURE

(76) Inventor: Michael Bostater, Lakeside, CA (US)

(21) Appl. No.: 12/879,913

(22) Filed: Sep. 10, 2010

(51) Int. Cl. H05K 7/00; B23P 11/00

(52) U.S. Cl. 248/278.1; 29/428

(57) ABSTRACT

A secure computer tablet enclosure in accordance with the present invention includes a back plate and a front frame. In their assembly, the front frame is affixed to the back plate using tamper-proof connectors to securely hold the computer tablet between them. This assembly is then engaged to an orienting mechanism that is affixed to a mount. More specifically, the orienting mechanism itself includes, in combination, a turning device for turning the computer tablet through a turning angle (α), a tilting device for tilting the computer tablet through a tilting angle (β), and a rotation device for rotating the computer tablet through a rotation angle (θ). Movements through the respective angles α, β and θ can be accomplished separately and simultaneously.

### FIELD OF THE INVENTION

The present invention pertains generally to systems for securing a computer tablet in an enclosure at a predetermined location. More particularly, the present invention pertains to systems that can selectively move a secured computer tablet into various operational orientations at a fixed location. The present invention is particularly, but not exclusively, useful as a secure enclosure that can selectively and simultaneously turn the enclosed computer tablet through a turning angle (α), tilt it through a tilting angle (β), and rotate it through a rotation angle (θ).

### BACKGROUND OF THE INVENTION

How an object can be effectively secured so that the risk of its theft or unauthorized removal will be minimized depends on several factors. For one, the nature and value of the object that is to be secured is a major consideration. For another, the environment and location of the object in the environment where the object is to be secured is important. Of specific interest here is how best to provide security for an electronic device (e.g. a computer tablet) that will be used individually by a sequence of different persons, at any time during the day, in a substantially public place. For example, consider the use of a computer tablet (e.g. an iPad®) in the lobby or business center of a large hotel.

In addition to physically securing a computer tablet so that the risk of theft or unauthorized removal is minimized, it is also of great importance that the computer tablet, when secured, will still be useable. This means that the operational controls of the computer tablet must be accessible, and that the display screen of the computer tablet must be moveable into an orientation where it can be conveniently viewed by a user(s). Further, in most operational contexts it is important that the security feature be effective, but relatively unobtrusive.

With the above in mind, it is an object of the present invention to provide an enclosure for a computer tablet that will effectively protect against an unwanted removal, or theft, of the computer tablet from a secure location. Another object of the present invention is to provide a secure enclosure for a computer tablet that allows the computer tablet to be selectively moved into a convenient operational orientation. Yet another object of the present invention is to provide a secure enclosure for a computer tablet that allows the computer tablet to be operationally useful while it is secured. Still another object of the present invention is to provide a secure enclosure for a computer tablet that is easy to use, is simple to manufacture and is comparatively cost effective.

### SUMMARY OF THE INVENTION

In accordance with the present invention, an enclosure is provided for securing a computer tablet. The purpose here is to protect against either theft or an unauthorized removal of the computer tablet from a secure location. Importantly, the enclosure is designed to allow for movements of the secured computer tablet into selected operational orientations. This feature is provided for the user's convenience when viewing the computer tablet's display screen. These movements, of course, must be possible while the computer tablet remains secure.

Essential components of the enclosure include a back plate, a front frame, an orienting mechanism and a mount. For the present invention, the front frame is formed with an aperture, and it has a plurality of control access ports that surround the aperture. Also, the back plate is formed with appropriate ventilation holes.

Structurally, the front frame and the back plate are securely affixed to each other to hold the computer tablet between them. Importantly, this is done so that the display screen of the computer tablet can be viewed through the aperture of the front frame. Also, with the front frame securely affixed to the back plate, a user must still have operational control over the computer tablet by contact with the computer tablet through access ports formed in the front plate. As envisioned for the present invention, the front frame is affixed to the back plate using tamper-proof connectors of a type well known in the pertinent art. The orienting mechanism is then used to hold the computer tablet, in combination with the back plate and front frame, on the mount.

For purposes of the present invention, the orienting mechanism includes, in combination, a turning device, a tilting device, and a rotating device. Further, the back plate (with the computer tablet affixed thereto by the front frame) is securely engaged to the mechanism. With this engagement, the back plate can be turned with the turning device through an angle α around a first axis. Also, the tilting device or the orienting mechanism can tilt the back plate around a pivot point on a second axis through an angle β. Further, the orienting mechanism may also allow rotation of the back plate through a rotation angle θ around a third axis.

A specific operational relationship between each of the three axes mentioned above for the orienting mechanism is necessary for its proper operation. In general, this relationship is characterized by having each axis perpendicular to at least one of the other axes. More specifically, in a preferred embodiment, both the first axis (i.e. turn axis) and the third axis (i.e. rotate axis) are perpendicular to the second axis (i.e. tilt axis). Preferably, within this relationship, the second axis (tilt) is perpendicular to the first axis (turn) at the pivot point, and all three axes intersect each other at the pivot point. For the preferred embodiment, the turn angle α has a turning range (measured from a turn base line) of approximately ±110°; the tilt angle β has a tilting range (measured from a tilt base line) of approximately ±45°; and the rotation angle θ has a rotation range (measured from a rotate base line) of approximately ±45°.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a front perspective view of a secure enclosure in accordance with the present invention;

FIG. 2 is a rear perspective view of a secure enclosure in accordance with the present invention;

FIG. 3 is an exploded view of the secure enclosure shown in FIG. 1; and

FIG. 4 is an exploded view of the secure enclosure shown in FIG. 2.

### DESCRIPTION OF THE PREFERRED EMBODIMENTS

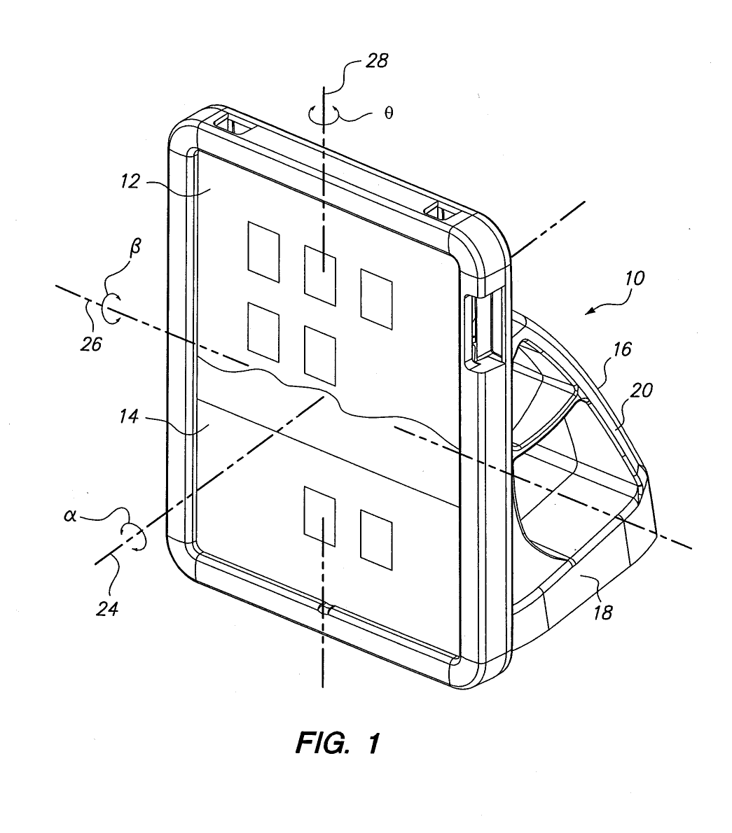

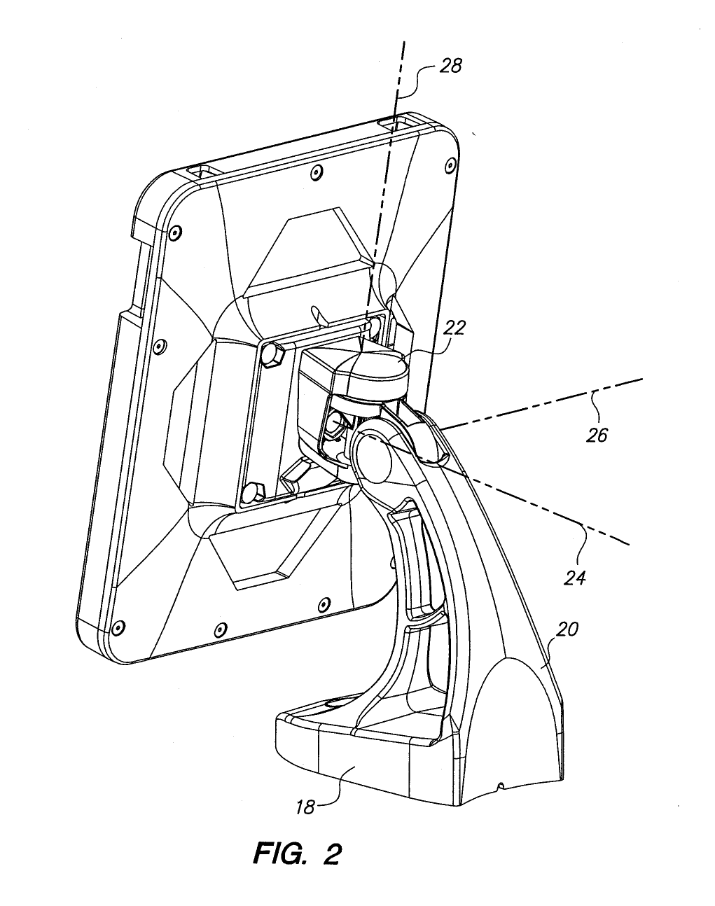

Referring initially to FIG. 1, a secure enclosure in accordance with the present invention is shown and is generally designated 10. As shown, the enclosure 10 is intended to securely support a computer tablet 12. Importantly, the computer tablet 12 is secured while a viewable display 14 on the computer tablet 12 is presented for an operational use of the computer tablet 12. Structurally, the enclosure 10 is perhaps best appreciated with reference to both FIG. 1 and FIG. 2. With this cross-reference, it can be seen that the enclosure 10 includes a mount 16 having a base 18 and an extension 20. As will be appreciated by the skilled artisan, the base 18 can be securely affixed to any support structure, such as a table or counter top (not shown). Further, the enclosure 10 includes an orienting mechanism 22 that is positioned on the mount 16 substantially as shown in FIG. 2.

Still referring to FIG. 1, the functionality of the enclosure 10 can be appreciated by recognizing that it allows for either independent or concerted movements of the computer tablet 12 by turning, tilting and/or rotating the computer tablet 12. Specifically, these independent movements are made possible by the orienting mechanism 22. In detail, the turning of computer tablet 12 involves turning it through a turn angle α around the axis 24. The tilting of computer tablet 12 involves tilting it through a tilt angle β around the axis 26. And, the rotation of computer tablet 12 involves rotating it through a rotation angle θ around the axis 28.

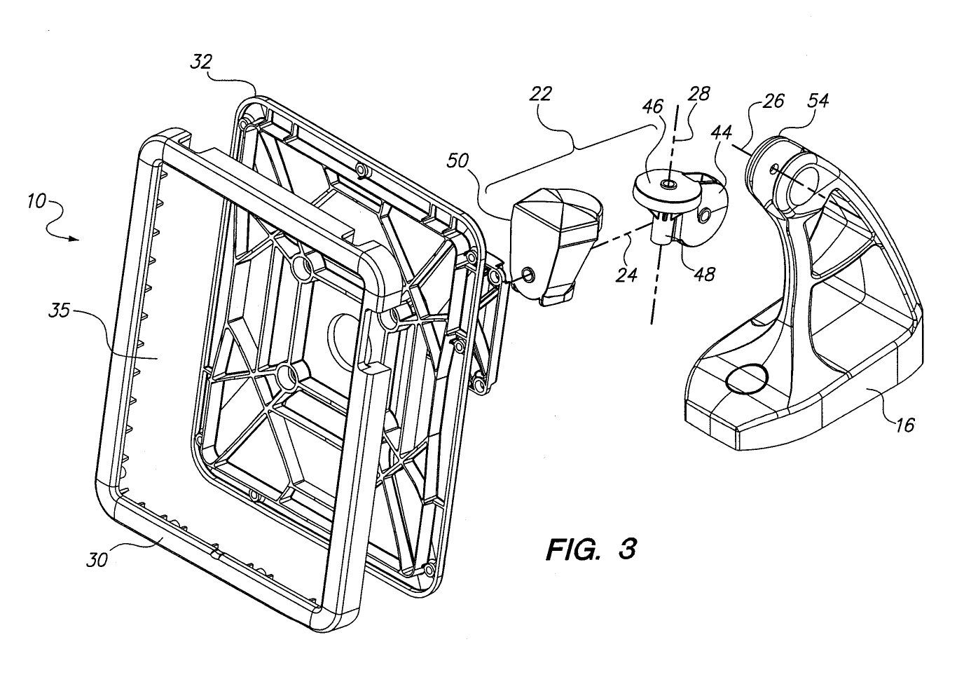

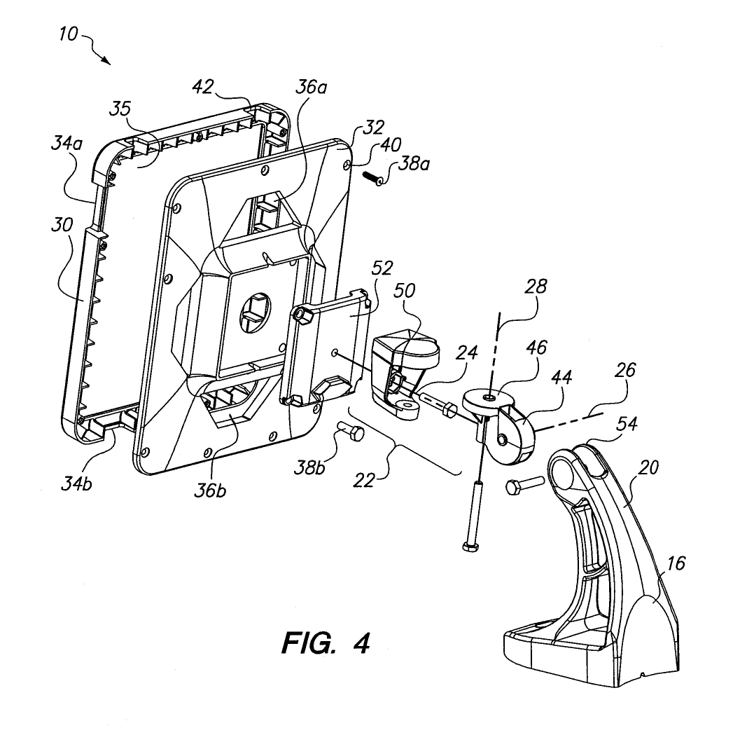

Turning now to FIG. 3, an exploded view of the present invention shows that the enclosure 10 includes a front frame 30 and a back plate 32. Further, as best seen in FIG. 4, the front frame 30 includes a plurality of access ports 34, of which the access ports 34a and 34b are only exemplary. Also the front frame 30 is formed with an aperture 35. Functionally, access ports 34 can be formed on the front frame 30 in order to provide access to controls (not shown) on the computer tablet 12, as necessary or desirable. Additionally, as shown, the back plate 32 includes a plurality of ventilation holes 36. Again, like access ports 34a and 34b, the ventilation holes 36a and 36b that are shown on the back plate 32 are only exemplary.

During an assembly of the enclosure 10, the computer tablet 12 is positioned between the front frame 30 and the back plate 32. A plurality of tamper-proof connectors 38 (e.g. screws), of which the connectors 38a and 38b are exemplary, are then used to affix the front frame 30 to the back plate 32. This is done to securely hold the computer tablet 12 between them. In this combination, the viewable display 14 of the computer tablet 12 can then be seen through the aperture 35 that is formed on the front frame 30. As an example of how the front frame 30 can be affixed to the back plate 32, connector (screw) 38a is passed through a screw hole 40 in the back plate 32. The connector 38a is then engaged with the screw receptacle 42 on front frame 30. The remaining connections are then made in a similar manner. As envisioned for the present invention, the tamper-proof connectors 38 can be of any type connector that is well known in the pertinent art, such as tamper proof screws. In any event, once the combination of the back plate 32, computer tablet 12, and front frame 30 has been assembled, the back plate 32 can then be engaged with the orienting mechanism 22.

Referring now to FIG. 3 and FIG. 4, the orienting mechanism 22 is shown to include a tilt plate 44 that is formed in combination with a rotate plate 46 which has an extension 48. Also, the orienting mechanism 22 is shown to include a housing 50 that will engage with a fixture 52. For an assembly of the mechanism 22, the tilt plate 44 is engaged with the set of brackets 54 that are formed on the extension 20 of mount 16. This engagement establishes a “tilt” movement through the angle “β” for the enclosure 10 about the tilt axis 26. Next, the rotate plate 46 and its extension 48 are engaged with the housing 50. This engagement establishes a “rotate” movement through the angle “θ” for the enclosure 10 about the rotate axis 28. Finally, the housing 50 is engaged with the fixture 52, for a “turn” movement of the fixture 52 through the angle “α” about the turn axis 24. The fixture 52 is then attached to the back plate 32 to provide for movements of the computer tablet 12. Thus, the enclosure 10 allows for individual or concerted movements of the computer tablet 12 through angles “α”, “β” and “θ” for respectively turning, tilting and/or rotating the computer tablet 12. Importantly, all of these movements can be made while the computer tablet 12 remains securely held by the enclosure 10. As envisioned for the enclosure 10 of the present invention, the angle α will have a turning range from a turn base line of approximately ±110°, the angle β will have a tilting range from a tilt base line of approximately ±45°, and the angle θ will have a rotation range from a rotate base line of approximately ±45°. Further, it is envisioned that the front frame 30, the back plate 32, the mount 16 and the orienting mechanism 22 are all made of glass filled nylon and acrylonitrile butadiene styrene (ABS).

While the particular Secure Computer Tablet Enclosure as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A secure computer tablet enclosure for moving the computer tablet into selected operational orientations which comprises:
a back plate for supporting the computer tablet, wherein the computer tablet has a viewable display;
a front frame formed with an aperture, wherein the front frame is securely affixed to the back plate for holding the computer tablet thereon for viewing the display through the aperture;
a mount formed with a base and an extension; and
an orienting mechanism attached to the extension of the mount, wherein the mechanism includes a turning device and a tilting device, and wherein the back plate is engaged to the mechanism for turning the back plate with the turning device through an angle α around a first axis, and for tilting the back plate with the tilting device through an angle β around a pivot point on a second axis, wherein the second axis is perpendicular to the first axis at the pivot point.

2. An enclosure as recited in claim 1 further comprising a plurality of tamper proof connectors for affixing the front frame to the back plate.

3. An enclosure as recited in claim 1 wherein the back plate is formed with a plurality of ventilation holes.

4. An enclosure as recited in claim 1 wherein the front frame is formed with a plurality of control access ports.

5. An enclosure as recited in claim 1 wherein the angle α has a turning range from a turn base line of approximately ±110°.

6. An enclosure as recited in claim 1 wherein the angle β has a tilting range from a tilt base line of approximately ±45°.

7. An enclosure as recited in claim 1 wherein the orienting mechanism further comprises a rotation device for rotating the back plate with the rotation device through an angle θ around a third axis.

8. An enclosure as recited in claim 7 wherein the third axis is perpendicular to the second axis.

9. An enclosure as recited in claim 8 wherein the angle θ has a rotation range from a rotate base line of approximately ±45°.

10. An enclosure as recited in claim 1 wherein the front frame, the back plate, the mount and the orienting mechanism are made of glass filled nylon and acrylonitrile butadiene styrene (ABS).

11. A secure computer tablet enclosure for moving the computer tablet into selected operational orientations which comprises:
a back plate for supporting the computer tablet, wherein the computer tablet has a viewable display;
a front frame formed with an aperture, wherein the front frame is securely affixed to the back plate for holding the computer tablet thereon for viewing the display through the aperture;
a mount formed with a base and an extension;
a rotation device affixed to the extension of the mount to provide for rotation of the rotation device on the mount around a rotation axis through an angle θ;
a tilting device engaged with the rotation device for tilting the tilting device around a tilt axis through an angle β; and
a turning device positioned to engage the tilting device with the back plate for turning the back plate around a turning axis through an angle α, wherein the turning axis passes through a pivot point at the intersection of the tilt axis and the rotation axis.

12. An enclosure as recited in claim 11 further comprising a plurality of tamper proof connectors for affixing the front frame to the back plate.

13. An enclosure as recited in claim 11 wherein the back plate is formed with a plurality of ventilation holes and the front frame is formed with a plurality of control access ports.

14. An enclosure as recited in claim 11 wherein the angle α has a turning range from a turn base line of approximately ±110°, wherein the angle β has a tilting range from a tilt base line of approximately ±45°, and the angle θ has a rotation range from a rotate base line of approximately ±45°.

15. An enclosure as recited in claim 11 wherein the front frame, the back plate, the mount and the orienting mechanism are made of glass filled nylon and acrylonitrile butadiene styrene (ABS).

16. A method for assembling a secure computer tablet enclosure which comprises the steps of:
positioning a computer tablet having a viewable display between a back plate and a front frame;
affixing the front frame to the back plate to securely hold the computer tablet therebetween, wherein the affixing step is accomplished using tamper proof connectors;
engaging the back plate to a mount for selective rotation of the computer tablet about three separate axes to selectively orient the computer tablet thereon, wherein each axis is perpendicular to at least one other of the three axes for rotation about a respective axis through a turn angle α, a tilt angle β, and a rotation angle θ.

17. A method as recited in claim 16 further comprising the steps of:
establishing a turn axis to measure the turn angle α;
establishing a tilt axis to measure the tilt angle β; and
establishing a rotation axis to measure the rotation angle θ.

18. A method as recited in claim 17 further comprising the step of aligning the tilt axis substantially perpendicular to the turn axis and to the rotation axis.

19. A method as recited in claim 18 wherein the angle α has a turning range from a turn base line of approximately ±110°, wherein the angle β has a tilting range from a tilt base line of approximately ±45°, and the angle θ has a rotation range from a rotate base line of approximately ±45°.

20. A method as recited in claim 16 further comprising the steps of:
forming the back plate with a plurality of ventilation holes; and
forming the front frame with an aperture for viewing the display, and with a plurality of control access ports.
